(19) United States
(12) Patent Application Publication
(10) Pub. No.: US 2006/0108616 A1
(43) Pub. Date: May 25, 2006

(54) High-voltage metal-oxide-semiconductor transistor

(75) Inventors: Lin-Kai Bu, Hsinhua (TW); Ying-Lieh Chen, Hsinhua (TW)

Correspondence Address: GENUS LAW GROUP, 1700 PENNSYLVANIA AVENUE , N.W., SUITT 400, WASHINGTON, DC, 20006, US

(73) Assignee: HIMAX TECHNOLOGIES, INC.

(21) Appl. No.: 10/992,784

(22) Filed: Nov. 22, 2004

(51) Int. Cl. H01L 29/94

(52) U.S. Cl. 257/288; 257/402; 257/412

(57) ABSTRACT

A high-voltage metal-oxide-semiconductor (HV MOS) transistor is provided to form the decoder in a source driver of a display apparatus for substantially saving the layout area. The HV MOS transistor includes two doped regions with a first conductivity type disposed in a semiconductor substrate, and a gate region having a second conductivity type opposite to the first conductivity type on the semiconductor substrate and between the doped regions. Accordingly, the layout area could be substantially reduced.

### BACKGROUND OF THE INVENTION

1. Field of the Invention

The invention relates to high-voltage metal-oxide-semiconductor transistors, and more particularly to high-voltage metal-oxide-semiconductor transistors utilized in a digital-to-analog circuit.

2. Discription of the Prior Art

In a thin-film-transistor liquid crystal display (TFT LCD), the source driver receives digital image data 110 and transfers the digital image data 110 to analog image data 120, which are then outputted to the LCD panel, by the digital to analog converter (DAC) 130, as shown in FIG. 1. FIG. 2 illustrates the 3-bit N-type DAC, and the decoder 140 is included. A 3-bit P-type DAC looks similar to the 3-bit N-type DAC but P-type metal-oxide-semiconductor (PMOS) transistors are adopted instead of N-type metal-oxide-semiconductor (NMOS) transistors. As shown in FIG. 2, there are 3 NMOS transistors in serial. For an m-bit decoder, there should be m MOS transistors in serial. The elements, such as metal-oxide-semiconductor transistors, that make up the decoder generally pertain to high-voltage type. The term “high voltage” is used in the semiconductor industry to indicate that the withstanding voltage of the gate of the metal-oxide-semiconductor transistor is greater than 8 volts, and such definition is therefore applied in this specification. It is noted, however, that this definition may be modified somehow according to the advance of technology in the future. In addition to the level of the supplied voltage, the high-voltage circuits have substantial different design rule from the low-voltage counterparts. Accordingly, the high-voltage circuits (or elements) require more layout area than the low-voltage circuits (or elements). Considering the source driver of the LCD, for example, the decoder of an 8-bit LCD driver almost occupies half of the layout area while designed and manufactured in conventional technique. Moreover, the occupying percentage of the layout area disadvantageously increases when the number of bits of the driver expands.

FIG. 3A and FIG. 3B schematically illustrate portions of a decoder circuit, including a series of high-voltage N-type metal-oxide-semiconductor (HV NMOS) transistors or high-voltage P-type metal-oxide-semiconductor (HV PMOS) transistors, respectively. The cross-sections of the HV NMOS transistors 200 and the HV PMOS transistors 210 based on the standard (or conventional) high-voltage devices offered by the conventional foundries are illustrated in FIG. 4A and FIG. 4B, respectively.

Specifically, the HV NMOS transistors 200 shown in FIG. 4A each includes a polysilicon gate 201, a gate oxide layer 202 between the polysilicon gate 201 and a P-substrate 205, N+ doped regions 203 and N-type Double Diffusion (NDD) regions 204 disposed in the substrate 205 and located between the ends of the gate oxide layers 202. Similarly, the HV PMOS transistors 210 shown in FIG. 4B each includes a polysilicon gate 211, a gate oxide layer 212 between the polysilicon gate 211 and an N-well 215, P+ doped regions 213 and P-type Double Diffusion (PDD) regions 214 disposed in the well 215 and located between the ends of the gate oxide layers 212.

Referring to the HV NMOS transistors 200 in FIG. 4A, some dimensions are designated among which, f is the length of the N+ doped regions 203, g denotes the distance between the adjacent ends (or borders) of the N+ doped regions 203 and the NDD regions 204, h denotes the distance between the other adjacent ends of the N+ doped regions 203 and the NDD regions 204, and w2 is the length of the polysilicon gate 201. Similarly, for the HV PMOS transistors 210 in FIG. 4B, a is the length of the P+ doped regions 213, b denotes the distance between the adjacent ends of the P+ doped regions 213 and the PDD regions 214, c denotes the distance between the other adjacent ends of the P+ doped regions 213 and the PDD regions 214, and w1 is the length of the polysilicon gate 211. In standard process, the ratio of a, b, c, f, g, h, w1, w2 is 1:1.8:1.8:1:1.8:1.8:3:3.

As mentioned earlier, the high-voltage circuits (or elements) require more layout area than the low-voltage circuits (or elements) by using the conventional design rule and the conventional element structure. This situation becomes prominently noticeable while regarding the design of the decoder of TFT LCD. Therefore, a need has been arisen for a new structure and design rule of high-voltage metal-oxide-semiconductor transistors, such that the layout area could be substantially reduced, and therefore making minimized or complex products plausible.

### SUMMARY OF THE INVENTION

Accordingly, it is an object of the present invention to provide high-voltage metal-oxide-semiconductor transistors having shortened source/drain region, thereby substantially reducing the layout area.

It is another object of the present invention to provide decoders of the source driver of a liquid crystal display having reducing circuit layout area, while maintaining functionality and performance.

In accordance with the present invention, a high-voltage metal-oxide-semiconductor field-effect-transistor (HV MOSFET) is disclosed. In one embodiment, the source/drain region includes a P/N double diffusion region (PDD or NDD) without further doped region enclosed therewithin. Accordingly, the source/drain region has a 0% to 20% length less than conventional design, and the layout area could be substantially reduced. In the second embodiment, the source/drain region includes a P/N doped region (P+ or N+) without forming further doped region. In the third embodiment, the source/drain region includes a P/N double diffusion region (PDD or NDD) with further doped region enclosed therewithin. The overlapping percentage of the length of the P/N doped region (P+ or N+) to the length of the P/N double diffusion region (PDD or NDD) could be 20% to 100%.

### BRIEF DESCRIPTION OF THE DRAWINGS

For a better understanding of the invention as well as other objects and features thereof, reference is made to the following detailed description to be read in conjunction with the accompanying drawings, wherein:

FIG. 1 illustrates the block diagram of a source driver.

FIG. 2 illustrates the circuit diagram of an N-type DAC.

FIG. 3A and FIG. 3B schematically illustrate portions of a decoder circuit in the prior art;

FIG. 4A and FIG. 4B illustrate the cross-sections of FIG. 3A and FIG. 3B, respectively, in the prior art;

FIG. 5A and FIG. 5B show the cross-sections of the HV NMOS and HV PMOS, respectively, according to one embodiment of the present invention;

FIG. 6A and FIG. 6B show the cross-sections of the HV NMOS and HV PMOS, respectively, according to the second embodiment of the present invention;

FIG. 7A and FIG. 7B schematically illustrate portions of a decoder circuit according to the present invention; and

FIG. 8A and FIG. 8B show the cross-sections of the HV NMOS and HV PMOS, respectively, according to the third embodiment of the present invention.

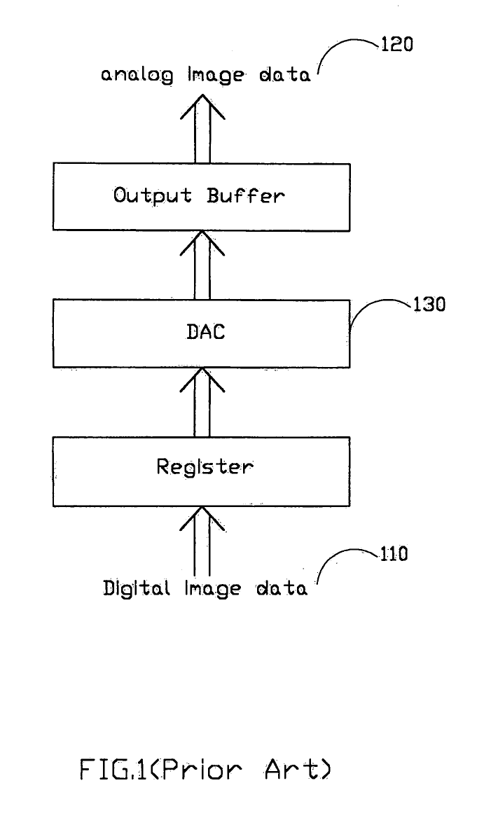

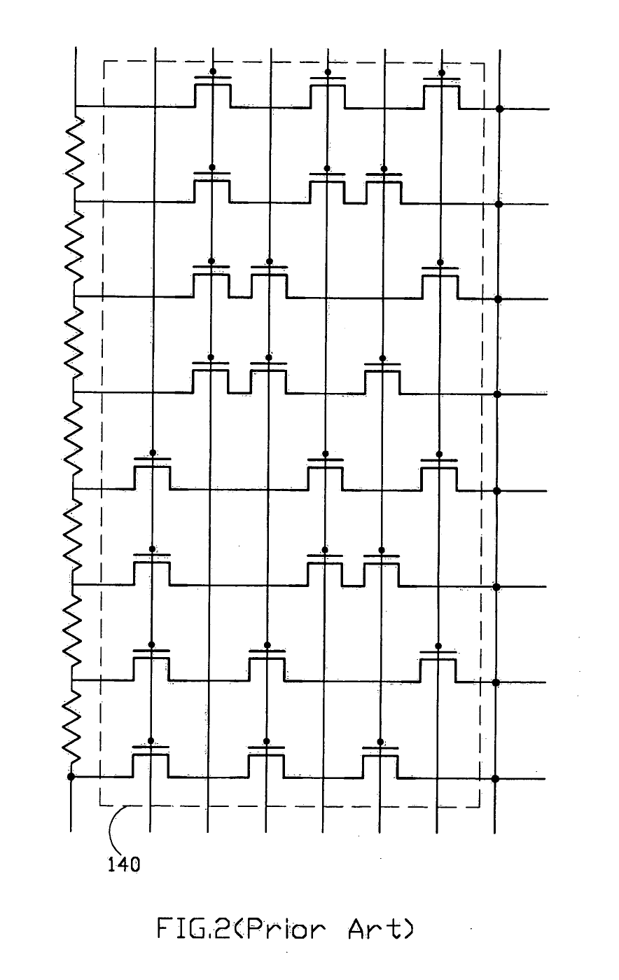

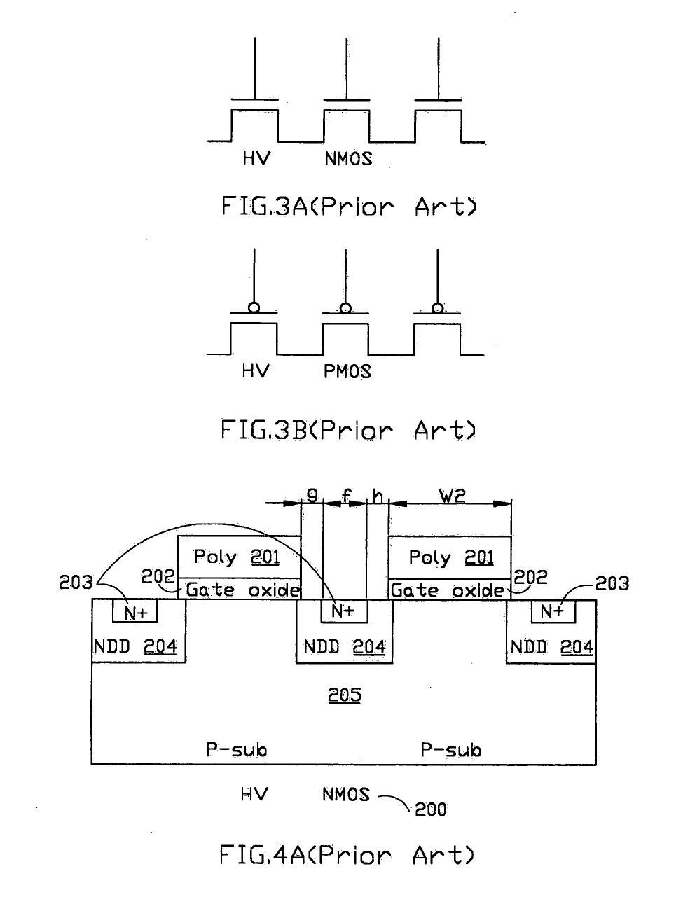

### DESCRIPTION OF THE PREFERRED EMBODIMENT

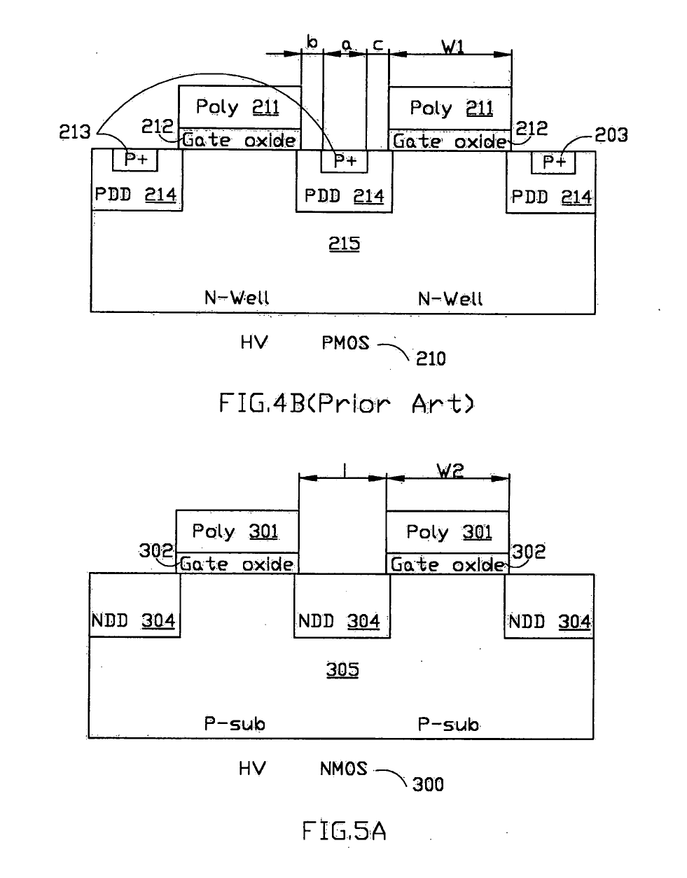

FIG. 5A shows a cross-section of a high-voltage N-type metal-oxide-semiconductor field-effect-transistor (HV NMOSFET or abbreviated as HV NMOS) 300 according to one embodiment of the present invention. Particularly, this HV MOSFET is used for, but not restricted to, implementing the decoders in a DAC of the source drivers of the liquid crystal display. The HV NMOS 300 includes a P-type semiconductor substrate 305, such as silicon substrate, on which gate oxide layers 302 are formed by a conventional process, such as oxidation. On the corresponding gate oxide layer 302 is a polysilicon (usually abbreviated as poly) layer 301, which is also formed by a conventional process, such as deposition. Consequently, a doped region 304 is formed in the substrate 305, and is disposed between the opposite edges of neighboring gate oxide layers 302. Specifically, in this embodiment, the doped region 304 acts as a source/drain region, and is doped by N-type atoms having a doping concentration of about 10¹⁴ cm⁻³-10²⁰ cm⁻³, which is performed by a double diffusion technique. Accordingly, the doped regions 304 are usually designated as NDD. It is worth noting at least that there is no further N+ doped region surrounded by the NDD 304, compared to that of FIG. 4A in the prior art. More particularly, the length i of the NDD 304 is substantially less than its counterpart (g+f+h) in FIG. 4A. The length i has dimension of about 0.1 um-29 um, compare with 30 um in the prior art. The length i having dimension of less 10%-30% than the prior art is prefer. Compared with standard process, the length i is less than 1.3 times the length w2. According to the embodiment of the present invention, and comparing to that of FIG. 4A, the resistance increase due to the omission of N+ region in the present invention could be compensated for resistance decrease due to the shortened dimension in the present invention.

FIG. 5B shows a cross-section of another HV MOS 310, in which a P-type HV MOS (PMOS) is disclosed instead of NMOS as in FIG. 5A. The HV PMOS 310 includes an N-type semiconductor substrate 315, such as silicon N-well, on which gate oxide layers 312 are formed, and a polysilicon layer 311 is then formed thereon. Consequently, a doped region 314 is formed in the N-well 315, and is disposed between the opposite edges of neighboring gate oxide layers 312. Specifically, in this embodiment, the doped region 314 is doped by P-type atoms, and is designated as PDD. Similarly, the length d of the PDD 314 is substantially less than its counterpart (a+b+c) in FIG. 4B. Compared with standard process, the length d is less than 1.3 times the length w1.

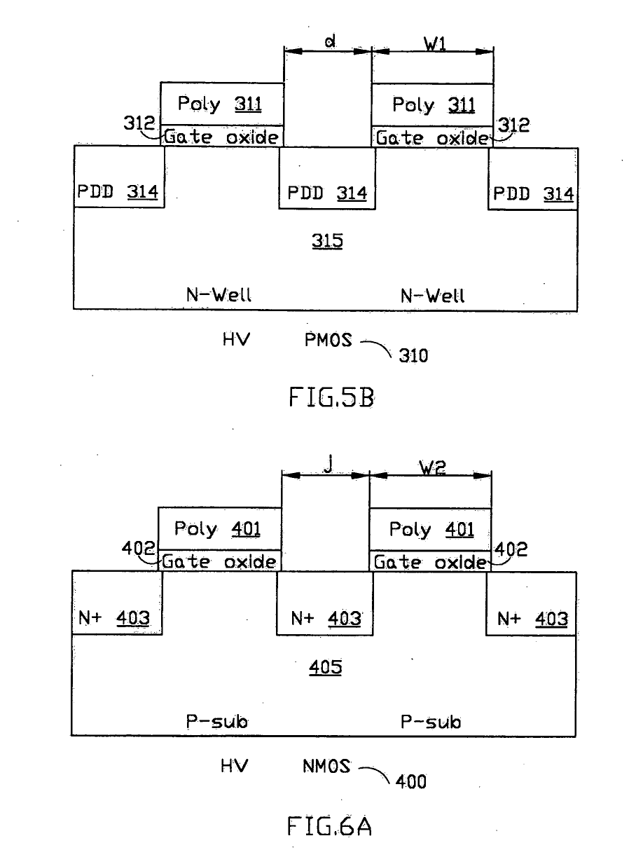

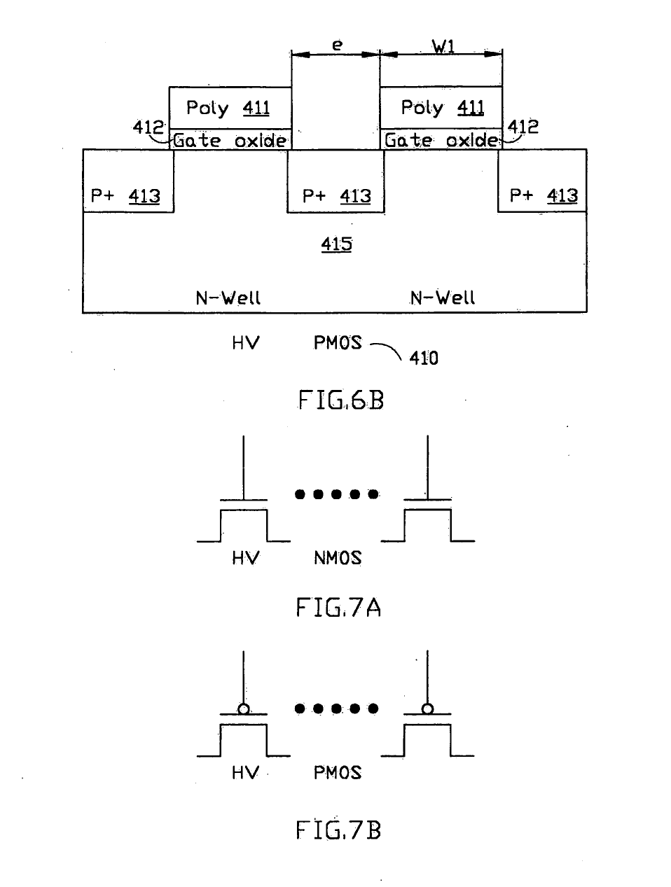

FIG. 6A shows a cross-section of a high-voltage N-type metal-oxide-semiconductor field-effect-transistor (HV NMOSFET or abbreviated as HV NMOS) 400 according to the second embodiment of the present invention. Particularly, this HV MOSFET is used for, but not restricted to, implementing the decoders of the source drivers of the liquid crystal display. The HV MOS 400 includes a P-type semiconductor substrate 405, such as silicon substrate, on which gate oxide layers 402 are formed by a conventional process, such as oxidation. On the corresponding gate oxide layer 402 is a polysilicon (usually abbreviated as poly) layer 401, which is also formed by a conventional process, such as deposition. Consequently, a doped region 403 is formed in the substrate 405, and is disposed between the opposite edges of neighboring gate oxide layers 402. Specifically, in this embodiment, the doped region 403 acts as source/drain region, and is doped by N-type atoms having a doping concentration of about 10¹⁷ cm⁻¹-10²¹ cm⁻³, which is performed by a conventional implantation or diffusion technique. Accordingly, the doped regions 403 are usually designated as N+. It is worth noting at least that there is no further NDD doped region surrounding the N+ region 403, compared to that of FIG. 4A in the prior art. More particularly, the length j of the N+ region 403 is substantially less than its counterpart (g+f+h) in FIG. 4A. The length j has dimension of about 0.1 um-29 um, compare with 30 um in the prior art. The length j having dimension of less 60%-85% than the prior art is prefer. Compared with standard process, the length j is less than 0.7 times the length w2. According to the embodiment of the present invention, and comparing to that of FIG. 4A, the resistance increase due to the omission of NDD region in the present invention could be compensated for resistance decrease due to the shortened dimension in the present invention.

FIG. 6B shows a cross-section of another HV MOS 410, in which a P-type HV MOS (PMOS) is disclosed instead of NMOS as in FIG. 6A. The HV PMOS 410 includes an N-type semiconductor substrate 415, such as silicon N-well, on which gate oxide layers 412 are formed, and a polysilicon layer 411 is then formed thereon. Consequently, a doped region 413 is formed in the N-well 415, and is disposed between the opposite edges of neighboring gate oxide layers 412. Specifically, in this embodiment, the doped region 413 is doped by P-type atoms, and is designated as P+. Similarly, the length e of the P+ region 413 is substantially less than its counterpart (a+b+c) in FIG. 4B. Compared with standard process, the length e is less than 0.7 times the length w1.

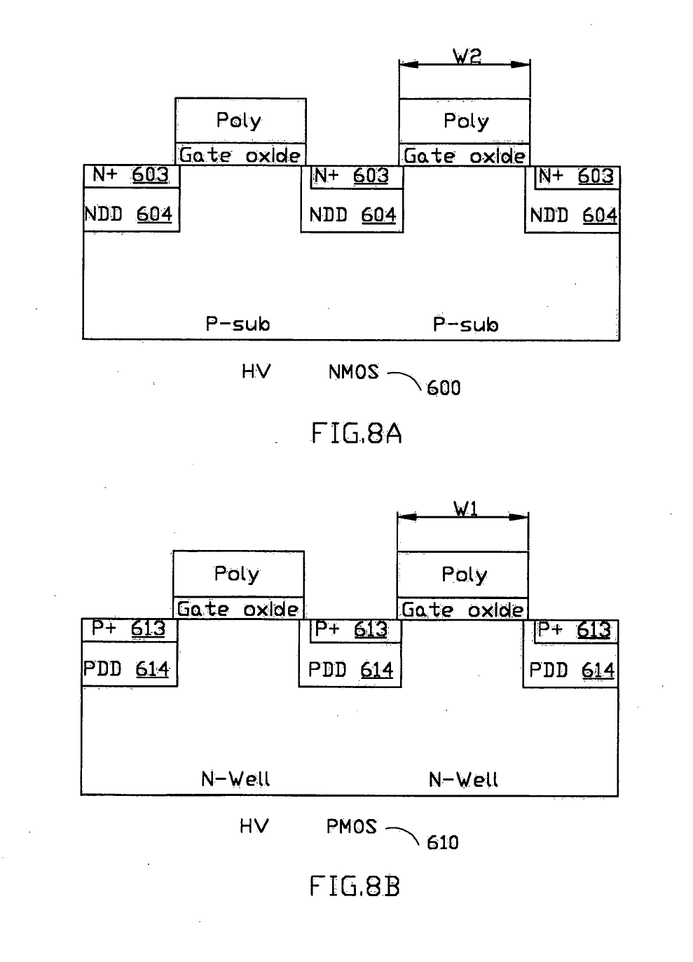

FIG. 7A and FIG. 7B, according to the present invention, schematically illustrate portions of a decoder circuit, including a series of high-voltage N-type metal-oxide-semiconductor (HV NMOS) transistors or high-voltage P-type metal-oxide-semiconductor (HV PMOS) transistors, respectively, which are implemented by the HV NMOS or HV PMOS as disclosed in the previous description concerning FIGS. 5A-6B, or FIGS. 8A-8B, which will be described later.

The present invention further discloses another embodiment as follows. FIG. 8A shows a cross-section of a high-voltage N-type metal-oxide-semiconductor field-effect-transistor (HV NMOSFET or abbreviated as HV NMOS) 600 according to the third embodiment of the present invention. The structure of FIG. 8A is similar to that of FIG. 5A, except that an N+ region 603 is further formed within the NDD 604. In this embodiment, the N+ region 603 has a doping concentration of about 10¹⁷ cm⁻³-10²¹ cm⁻³, and the NDD 604 has a doping concentration of about 10¹⁴ cm⁻³-10²⁰ cm ⁻³. It is particularly noted that the overlapping percentage of the length of the N+ region 603 to the length of the NDD 604 could be 20% to 100%. More particularly, a portion of the N+ region 603 can be between the gate oxide and the NDD 604. Compared with standard process, the length of the NDD 604 is 1 to 5 times the length of the N+ region 603. According to the embodiment of the present invention, and comparing to that of FIG. 4A, the resistance decrease due to the shorted dimension in the present invention could be accompanied by increasing the doping concentration of the N+ region 603 or NDD region 604, or by adjusting the overlapping percentage of the length of the N+ region 603 to the length of the NDD 604.

FIG. 8B shows a cross-section of another HV MOS 610, in which a P-type HV MOS (PMOS) is disclosed instead of NMOS as in FIG. 8A. The structure of FIG. 8B is similar to that of FIG. 5B, except that a P+ region 613 is further formed within the PDD 614. More particularly, a portion of the P+ region 613 can be between the gate oxide and the PDD 614. Compared with standard process, the length of the PDD 614 is 1 to 5 times the length of the P+ region 613.

The foregoing is disclosed primarily for purpose of illustration. It will be readily apparent to those skilled in the art that the operating conditions, materials, procedural steps and other parameters of the device described herein may be further modified or substituted in various ways without departing from the spirit and scope of the invention.

What is claimed is:

1. A metal-oxide-semiconductor (MOS) transistor, comprising:
a substrate;
a source disposed in the substrate;
a drain disposed in the substrate;
a gate intermediate the source and the drain, wherein a withstanding voltage of the gate is greater than 8 volts, and a length of the source is less than 1.3 times the length of the gate.

2. The MOS transistor according to claim 1, wherein the substrate includes a doped well.

3. The MOS transistor according to claim 1, wherein the source is performed by a double diffusion technique.

4. The MOS transistor according to claim 3, wherein the source has a doping concentration between 10¹⁴ cm⁻³ and 10²⁰ cm⁻¹.

5. The MOS transistor according to claim 1, wherein a length of the drain is less than 0.7 times the length of the gate.

6. The MOS transistor according to claim 5, wherein the drain is performed by a diffusion technique.

7. The MOS transistor according to claim 6, wherein the drain has a doping concentration between 10¹⁷ cm⁻³ and 10²¹ cm⁻³.

8. The MOS transistor according to claim 1, wherein the drain has a first doped region and a second doped region, and a portion of the first doped region is disposed between the gate and the second doped region.

9. The MOS transistor according to claim 8, wherein the first doped region is performed by a diffusion technique and the second doped region is performed by a double diffusion technique.

10. The MOS transistor according to claim 9, wherein a length of the second doped region is 1 to 5 times the length of the first doped region.

11. The MOS transistor according to claim 1, wherein the MOS transistor is adopted in a decoder.

12. The MOS transistor according to claim 11, wherein the decoder is adopted in a source digital to analog converter (DAC).

13. The MOS transistor according to claim 11, wherein the DAC is adopted in a source driver.
